(19) United States
(12) Patent Application Publication
(10) Pub. No.: US 2023/0385208 A1
(43) Pub. Date: Nov. 30, 2023

(54) ACCELERATED MEMORY TRAINING THROUGH IN-BAND CONFIGURATION REGISTER UPDATE MODE

(71) Applicant: Intel Corporation, Santa Clara, CA (US)

(72) Inventors: Saravanan SETHURAMAN, Portland, OR (US); Tonia M. ROSE, Wendell, NC (US)

(21) Appl. No.: 18/232,765

(22) Filed: Aug. 10, 2023

(51) Int. Cl. G06F 13/16; G06F 13/36

(52) U.S. Cl. CPC G06F 13/1668; G06F 13/36

(57) ABSTRACT

A configuration register update mode can be implemented as a register word update (RWUPD) mode for a registering clock driver (RCD) or as a mode register update (MRUPD) mode for a dynamic random access memory (DRAM) device. In the update mode, In the update mode, the memory device (either the RCD or the DRAM) can perform configuration of any number of configuration registers with in-band register writes. The in-band register writes can be used to configure decision feedback equalization (DFE) settings, as well as other configuration settings for non-DFE configurations of a memory device interface.

### TECHNICAL FIELD

Descriptions are generally related to computer memory, and more particular descriptions are related to memory interface training.

### BACKGROUND OF THE INVENTION

Programming the RCD before the command/address (CA) bus and data (DQ) bus are trained has been performed by use of a sideband bus, such as the system management bus (SMBus). Sideband buses operate at a very low speed (on the order of megahertz (MHz)) relative to the CA bus and the DQ bus (on the order of gigahertz (GHz)). The use of a sideband bus for training can result in significant delays in the training.

The registering clock driver (RCD) defines an in-band training available for training option for the decision feedback equalization (DFE) configuration. The RCD in-band training defines entry into a register word update (RWUPD) mode. In the RWUPD mode, the RCD can receive configuration updates until there is a trigger to exit the update mode. Since the RWUPD mode is limited to DFE configuration, its scope is limited for training.

It will also be understood that updates to configuration of a dynamic random access memory (DRAM) device can be performed through mode register (MR) writes. The writes have been performed by the DRAM device in response to a mode register write (MRW) command sent to the DRAM device. A memory controller traditionally needs to train the CA bus before a command such as MRW can be reliably sent to the DRAM device.

### BRIEF DESCRIPTION OF THE DRAWINGS

The following description includes discussion of figures having illustrations given by way of example of an implementation. The drawings should be understood by way of example, and not by way of limitation. As used herein, references to one or more examples are to be understood as describing a particular feature, structure, or characteristic included in at least one implementation of the invention. Phrases such as “in one example” or “in an alternative example” appearing herein provide examples of implementations of the invention, and do not necessarily all refer to the same implementation. However, they are also not necessarily mutually exclusive.

FIG. 1 is a block diagram of an example of a system with a memory module.

FIG. 2 is a block diagram of an example of a memory module with an RCD having an in-band configuration mode.

FIG. 3 is a block diagram of an example of a memory module with memory devices having an in-band configuration mode.

FIG. 4 is an example of a table for an RWUPD mode.

FIG. 5 is an example of a table for an MRUPD mode.

FIG. 6 is an example of a table for an MRUPD mode that also uses M3C.

FIG. 7 is a flow diagram of an example of a process for RWUPD.

FIG. 8 is a flow diagram of an example of a process for MRUPD.

FIG. 9 is a state diagram of an example of MRUPD.

FIG. 10 is a block diagram of an example of a memory subsystem in which an in-band configuration mode can be implemented.

FIG. 11 is a block diagram of an example of a computing system in which in-band configuration mode can be implemented.

FIG. 12 is a block diagram of an example of a multi-node network in which in-band configuration mode can be implemented.

Descriptions of certain details and implementations follow, including non-limiting descriptions of the figures, which may depict some or all examples, and well as other potential implementations.

### DETAILED DESCRIPTION OF THE INVENTION

As described herein, a configuration register update mode can be implemented as a register word update (RWUPD) mode for a registering clock driver (RCD) or as a mode register update (MRUPD) mode for a dynamic random access memory (DRAM) device. In the update mode, the memory device (either the RCD or the DRAM) can perform configuration of any number of configuration registers with in-band register writes. The in-band register writes can be used to configure decision feedback equalization (DFE) settings, as well as other configuration settings for non-DFE configurations of a memory device interface.

As described herein, in-band communication can be used for the training of any DRAM register or RCD register before the chip select (CS) is trained. In one concept, there is an extension/enhancement of the register word update (RWUPD). RWUPD has been limited to device command/address training mode (DCATM) and DFE and can be expanded to the updating of any register or any register word. Thus, the system can update register word configuration through the RWUPD mode. Extending RWUPD to the updating of other registers avoids the use of the SMBus, increasing the speed of training and setup. In another concept, there is a mode register update (MRUPD). The MRUPD extends the idea of register updating with in-band communication. The use of MRUPD can replace MPC. When the buses are not fully trained, the system can use in-band communication to train.

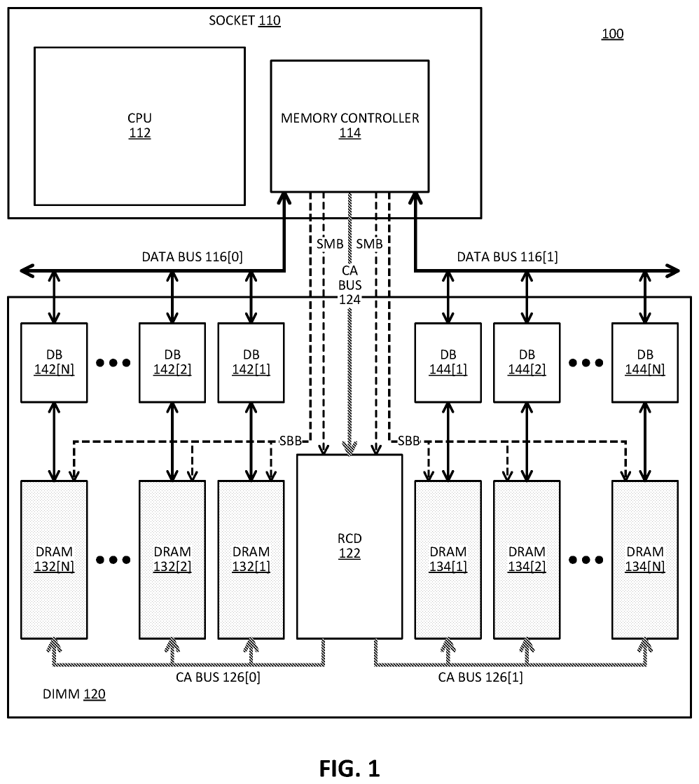

FIG. 1 is a block diagram of an example of a system with a memory module. System 100 includes socket 110 coupled to DIMM 120. Socket 110 represents a CPU socket, which can include CPU 112 and memory controller 114. DIMM 120 includes multiple DRAM devices.

System 100 illustrates an example of a system with memory devices that share a control bus or command bus (command/address (C/A) bus 126[0] for one channel and C/A bus 126[1] for the other channel) and data buses (data bus 116[0] for the one channel and data bus 116[1] for the other channel). The memory devices are represented as DRAM (dynamic random access memory) devices. Each channel has N DRAM devices, DRAM 132[1:N] (collectively, DRAM devices 132) for one channel, and DRAM 134[1:N] (collectively, DRAM devices 134) for the other channel, where N can be any integer. In one example, N includes one or more (error checking and correction (ECC) DRAM devices in addition to the data devices. Each DRAM device 132 and each DRAM device 134 can represent a memory chip with a command bus interface to memory controller 114, where the interface can be through RCD 122.

In one example, the two separate channels share C/A bus 124 connection between memory controller 114 and RCD 122. In one example, the separate channels will have separate C/A buses. The DRAM devices can be individually accessed with device specific commands and can be accessed in parallel with parallel commands.

Registering clock driver (RCD) 122 (which can also be referred to as a registered clock driver) represents a controller for dual inline memory module (DIMM) 120. In one example, RCD 122 receives information from memory controller 114 and buffers the signals to the various DRAM devices. By buffering the input command signals from memory controller 114, the controller only sees the load of RCD 122 on the command/address (CA bus 124), which can then control the timing and signaling to the DRAM devices.

In one example, RCD 122 controls the command signals to DRAM devices 132 through CA bus 126[0] and controls the signals to DRAM devices 134 through CA bus 126[1]. In one example, RCD 122 has independent command ports for separate channels. In one example, DIMM 120 includes data buffers to buffer the data bus signals between the DRAM devices of DIMM 120 and memory controller 114.

Data bus 116[0] provides a data bus for DRAM devices 132, which are buffered with data buffer (DB) 142[1:N] (collectively, DBs 142). Data bus 116[1] provides a data bus for DRAM devices 134, which are buffered with data buffer (DB) 144[1:N] (collectively, DBs 144). System 100 illustrates a one-to-one relationship between data buffers and DRAM devices. In one example, there are fewer data buffers than DRAM devices, with DRAM devices sharing a data buffer.

CA bus 126[0] and CA bus 126[1] (collectively, CA buses 126) are typically unilateral buses or unidirectional buses to carry command and address information from memory controller 114 to the DRAM devices. Thus, CA buses 126 can be multi-drop buses. Data bus 116[0] and data bus 116[1], collectively data buses 116, are traditionally bidirectional, point-to-point buses.

In one example, memory controller 114 includes one or more sideband bus connections to other devices in system 100. The sideband buses refer to buses other than CA bus 124 and other than data buses 116. As illustrated, memory controller 114 has system management bus (SMBus, illustrated in system 100 as “SMB” for simplicity) to connect to RCD 122. In one example, memory controller 114 has the SMBus connection or other sideband bus (SBB) to connect to the DRAM devices. In one example, the SBB connection represents a memory module management control (M3C) bus. Both the SMBus and SBB connections represent sideband bus communication in system 100.

The sideband bus enables memory controller 114 to provide a command to a device through a connection other than the CA bus. Communication on a sideband bus is not in-band, because the command is not received on the CA bus. In one example, the communication on the sideband bus enables memory controller 114 to send commands to trigger a device into a pre-training update mode that uses in-band communication to perform configuration updates.

In one example, system 100 supports an RWUPD mode to configure the RCD interface to CA bus 124. In one example, system 100 supports an MRUPD mode to configure the DRAM devices. The configuration of the DRAM devices can include configuration of the data bus interface, configuration of the CA bus interface, or configuration of both the CA bus interface and the data bus interface. With the update modes, system 100 supports writing configuration parameters in-band prior to training the chip select (CS).

With the update modes, in one example, system 100 can accelerate backside and front side training for all parametric sweeps. With the increase of in-band commands to perform the configuration, system 100 can reduce sideband bus usage. Due to the significant difference in speed between in-band communication and out-of-band communication (e.g., sideband bus usage), where in-band communication can be orders of magnitude faster, the use of in-band communication for configuration updates can improve system boot time.

CA bus 124 provides a link for memory controller 114 to provide command and address information to identify a command to be executed, and the address for execution of the command. It will be understood that the interface to the command bus (e.g., CA bus 124) can be trained to identify preferred settings to ensure proper receipt of the commands at RCD 122. The training can include iterating through different configuration settings to determine a setting with the best performance, which can vary from system to system.

With the introduction of a double data rate (DDR) mode for command buses, the interface to the command bus can include decision feedback equalization (DFE) with multiple taps (e.g., 2 or 4 taps) to ensure a proper data eye on the CA signal lines. DFE refers to a nonlinear equalization circuit that utilizes information about prior bits received to determine a current bit being received and processed. Other configuration settings can include reference voltage settings, current settings, and other configuration settings. The training sets the parameters to ensure proper communication on the command bus.

In one example, where system 100 supports an MRUPD mode, the update mode can reduce or eliminate the need for multipurpose commands (MPC commands) for configuration. In one implementation, system 100 can replace MPC commands, replace voltage reference for chip select (VrefCS) command, and replace voltage reference for command/address (VrefCA) command. Full use of the MRUPD mode for all training can enable removal of the MPC encoded opcode table. Alternatively, a system can limit the opcode to a few commands. Both removing and reducing the MPC opcodes can save hardware logic within the DRAM devices.

The MRUPD mode and the RWUPD mode described can enable configuration for all possible training modes. In one example, enabling the configuration for all training modes includes the following: triggering the device to enter the update mode (e.g., an SMBus command to trigger RWUPD entry (RWUPDE), or an M3C command to trigger MRUPD entry (MRUPDE)), issues configuration write operations with two commands, including one for the register address, and another for the configuration data value. The register write operations are in-band command, which speeds up the setting of configuration.

Alternatively to triggering MRUPDE with an M3C command, in one example, the DRAM devices can enter MRUPD mode by default after power on. The system can trigger the end of the update mode with an RWUPD exit (RWUPDX) command for the RCD or an MRUPD exit (MRUPDX) command for a DRAM. The exit command can terminate the update loop of issuing configuration register writes.

What is described above can work for the CA bus in double data rate DDR mode. If the DRAM defaults to the MRUPD mode/state right after power-on, the system can perform MRUPD before chip select training mode (CSTM) and before command/address training mode (CATM). Such operation can set up termination and Vref values through an in-band command rather than using sideband communication. While the MRUPD can replace MPC with a single cycle command, it may require a multicycle chip select feature.

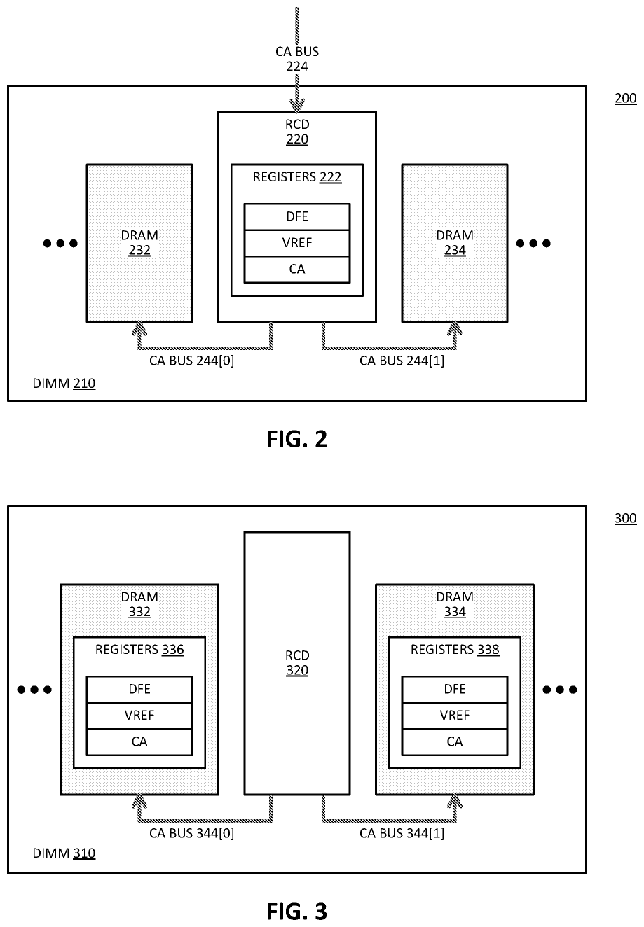

FIG. 2 is a block diagram of an example of a memory module with an RCD having an in-band configuration mode. System 200 illustrates a system in accordance with an example of system 100.

System 200 includes dual inline memory module (DIMM) 210, which represents a memory module with a module controller. RCD 220 represents the module controller. RCD 220 connects to a host (not specifically illustrated) via CA bus 224. RCD 220 has an interface to CA bus 224, which can be configured through setting values of registers 222.

Registers 222 can include, but are not limited to, DFE settings and termination settings. Each register can include one or more configuration setting. Registers 222 specifically illustrates DFE to represent configuration settings for the DFE for CA bus 224, VREF to represent Vref configuration settings, and CA to represent other settings such as termination settings or other configuration for CA bus 224.

RCD 220 can connect to DRAM devices 232 via CA bus 244[0] and to DRAM devices 234 via CA bus 244[1]. In one example, the configuration of registers 222 applies to the interface to CA bus 224, and the DRAM devices will have separate configuration for the CA bus interconnection from RCD 220.

Extending the RWUPD mode for RCD 220 can enable system 200 to finish DCSTM in RWUPD, applying in-band communication to set the configuration. In one example, RCD 220 enters RWUPD with SMBus communication, and exits RWUPD in response to a CS assertion. In one example, system 200 has a setup/configuration qualifier when RCD 220 is in RWUPD. The qualifier can be, for example, a chip select (e.g., DCS0/1), where assertion of the chip select can determine which channel is configured. In one example, each training mode can indicate which qualifier is used for the specific training. The training mode qualifier can be the opposite of RWUpdate qualifier.

In one example, the host can send the register address (e.g., RW address) and opcode for the RWUPD operation, and internally loop through the update operations (e.g., with hardware acceleration) using an RWUPD qualifier. In one example, system 200 triggers RCD 220 to exit RWUPD with a write to an RCD register (RW32) or through an SMBus command. In one example, registers 222 can include the RW32 RCD register.

RWUPD can be enhanced to all training steps (instead of just DFE). In one example, the RWUPD enhancement can include modifications to reduce significant training time (for both front side and backside) and logic in the RCD.

In one example, RWUPD entry occurs when the RCD is in training mode and DCS1_[B:A]_n is asserted. RWUPD operation involves the memory controller sending pairs of DCS1_[B:A]_n assertions. On the first assertion, the device samples the target RW address on {DCA[6:0]_[B:A], DPAR_[B:A]}. On the second assertion, the device samples the value to write to the target RW. The RWUPD exit can involve writing to a register word, such as writing a one to RW32[7], which can trigger the RCD to exit the RWUPD branch and return to the starting training mode state.

FIG. 3 is a block diagram of an example of a memory module with memory devices having an in-band configuration mode. System 300 illustrates a system in accordance with an example of system 100 or an example of system 200.

System 300 includes dual inline memory module (DIMM) 310, which represents a memory module with a module controller. RCD 320 represents the module controller. RCD 320 connects to a host (not specifically illustrated). RCD 320 can connect to DRAM devices 332 via CA bus 344[0] and to DRAM devices 334 via CA bus 344[1].

In one example, DRAM devices 332 include registers 336 and DRAM devices 334 include registers 338. In one example, the configuration of registers 336 applies to the interface of DRAM devices 332 to CA bus 344[0]. In one example, the configuration of registers 338 applies to the interface of DRAM devices 334 to CA bus 344[1].

Registers 336 and registers 338 can include, but are not limited to, DFE settings and termination settings. Registers 336 and register 338 specifically illustrate DFE to represent a DFE configuration register to store one or more configuration settings for the DFE for the CA buses, VREF to represent Vref configuration settings, and CA to represent other settings such as termination settings or other configuration for the CA buses. In one example, MRUPD can apply to all configuration settings in the DRAM devices for the CA buses. MRUPD can provide a training mode for all configuration register training for the CA bus.

System 300 enables a DRAM mode register update (MRUPD) mode. In one example, the MRUPD mode has an MRUPD entry (MRUPDE) and MRUPD exit (MRUPDX). In one example, MRUPD applies to a double data rate version 6 (DDR6). In one example, MRUPD is used in conjunction with a memory module management control (M3C) bus. An application of MRUPD mode can replace MPC commands, VrefCA and VrefCS commands. Without such commands, the MPC opcode table would not be required. Removal of the table saves logic in the DRAM and enables the mode register to be accessed any time, and without restriction to any set.

In one example, MRUPD in DRAM provides an update mode to be used by the DRAM for all training steps. With the proposed MRUPD, to sweep any parameter, the system does not need to go through SMBus access, which is significantly slower than in-band commands. Performing training through the in-band access accelerates the backside training steps such as CSTM, CATM, and DFE training algorithms and improves system boot time.

In one example, the in-band register writes are mode register writes (MRWs) based on commands on the command bus prior to execution of a command/address training mode (CATM). In one example, system 300 provides a first multipurpose command (MPC) to enter MRUPD mode. A second MPC can trigger an exit from the MRUPD mode.

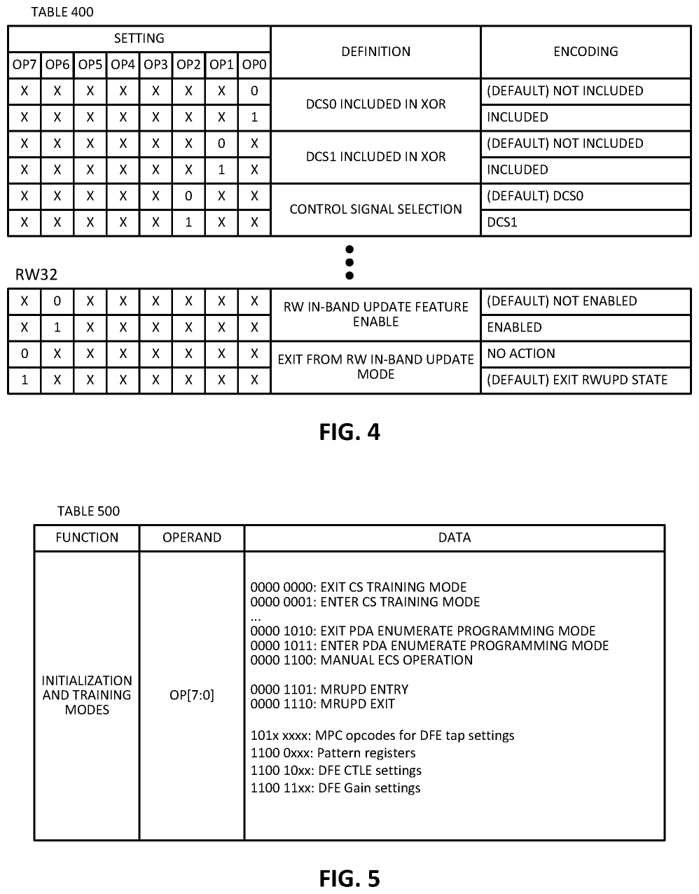

FIG. 4 is an example of a table for an RWUPD mode. Table 400 illustrates various opcodes. Table 400 includes opcode bits (OP[0:7]) that are the setting column. The definition column describes the settings, and the encoding column provides details on the settings.

The opcode that configures whether DCS0 is included in the exclusive OR operation (XOR) can be set with OP0=0 to not include DCS0 (the default setting), or with OP0=1, DCS0 can be included. The opcode that configures whether DCS1 is included in the XOR can be set with OP1=0 to not include DCS1 (the default setting), or with OP1=1, DCS1 can be included. The opcode that configures the control signal selection can be set with OP2=0 to select DCS0 (the default setting), or with OP2=1, DCS1 can be selected.

In one example, there is a register word (RW) in-band update feature where enablement is controlled by OP6, with OP6=0 the RWUPD feature is not enabled, which is the default setting, and with OP6=1 the RWUPD feature is enabled. In one example, the exit from RWUPD can be controlled by OP7, with OP7=0 resulting in taking no action, leaving the system in RWUPD, and with OP7=1 resulting in exit from the RWUPD state (the default setting).

With table 400, the following notes can be added to describe the opcode definitions:
Note A: DCS0 line—If RWUPD is enabled, DCS1 will be the qualifier. DCS1 will not take part in XOR.
Note B: DCS1 line—If RWUPD is enabled, DCS0 will be the qualifier. DCS0 will not take part in XOR.
Note C: User can use RWUPD to change the RWUPD DCS qualifier in a single register setting using prior DCS qualifier.

Separating out RWUPD with other training modes, to enable it to be used for other purposes. RW7E can define a new mode and leave in RW32 as it is for legacy.

The descriptions related to RWUPD refer specifically to the configuration of RCD settings. The descriptions related to MRUPD refer specifically to the configuration of DRAM settings. The concepts of in-band communication for setting the configuration apply to both RWUPD and MRUPD.

There can be different options for the application of MRUPD.

Option 1 applies M3C and MRUPD. With such an architecture, the use of M3C can reduce the training time. The system can use M3C communication to trigger MRUPDE and MRUPDX. The system can use MRUPD to configure all DRAM mode registers, where the CS can be a qualifier for MRUPD (e.g., use CS1 as a qualifier to train CS0 and use CS0 as a qualifier to train CS1). The system can use a multicycle CS for MRUPD to enter the CSTM training and exit with a double CS. In Option 1, the system can switch to the other CS, and change the values using MRUPD. The system can then use the M3C command to exit. With this architecture, M3C can be used for initialization such as terminations, device ID, and so forth.

The flow for Option 1 can be described in accordance with an example of process 800. Advantages of Option 1 include: 1) the configuration is significantly faster than SMBus training, even when MRUPD is a double command (one for Address and one for Data), 2) elimination of VrefCA and VrefCS MPC encoding and commands, 3) potential removal of MPC commands and opcode tables, and 4) enabling of MRUPD mode entry by default on DRAM power up, which can avoid M3C commands.

FIG. 5 is an example of a table for an MRUPD mode. Table 500 describes an application of Option 2 for an implementation of MRUPD. Table 500 includes a function of initialization and training modes, based on OP[7:0]. The data column describes different modes. Selected modes are illustrated, while other modes are left out.

Opcode “0000 0000” indicates exit from CS training mode (CSTM).

Opcode “0000 0001” indicates enter CSTM.

Opcode “0000 1010” indicates exit from per device addressability (PDA) enumerate programming mode.

Opcode “0000 1011” indicates enter PDA enumerate programming mode.

Opcode “0000 1100” indicates manual error checking and scrub (ECS) operation.

In one example, Option 2 applies MPC and M3C (without MRUPD). With such an architecture, additional opcodes can provide additional functionality. The timing of command/address signal lines (QCA) and chip select signal line (QCS) can be controlled by a continuous time linear equalizer (CTLE) and DFE 1-tap, which could involve hundreds of register accesses to set the configuration.

The M3C bus speed can be a controlling factor to train CA and CS signals. In one example, the system encodes the MPC opcodes to account for the DFE tap setting programming. There can be two settings for gain and two more for CTLE. The use of the MPC would consume command bandwidth, while also reducing the burden on the M3C. Such an architecture would keep VrefCA, VrefCS, and MPC as it is, as compared to replacing them as in Option 1. The logic can be reduced with inbuilt DRAM logic to perform auto sweep and internally compare with the pattern. With Option 2, M3C can be used for initialization setup such as terminations, device ID, and so forth, as well as for debug and validation. The use for debug and validation can avoid some of the MPC commands upfront.

In one example, Option 2 could include new MPC opcodes. The ‘x’ indicates a variable, and thus, the opcodes with ‘x’ can indicate a range.

Opcode “0000 1101” can be an MRUpdate mode entry (MRUPDE) (by default).

Opcode “0000 1110’ can be an MRUpdate mode exit (MRUPDX).

Opcodes “101x xxxx” can indicate MPC opcodes for DFE tap settings.

Opcodes “1100 0xxx” can be for pattern registers.

Opcodes “1100 10xx” can be used for DFE CTLE settings.

Opcodes “1100 11xx” can be used for DFE gain settings.

It will be understood that the use of so many opcodes could significantly reduce the number of opcodes available for MPC commands.

In one example, as described, there are in-band register writes based on commands on the command bus, without use of a sideband bus. As such, the register writes can be RW writes without use of the SMBus. The register writes can be mode register writes without use of a sideband bus. In one example, as described, there can be in-band register writes in combination with use of the SMBus. The register writes can be mode register writes in combination with the use of a sideband bus.

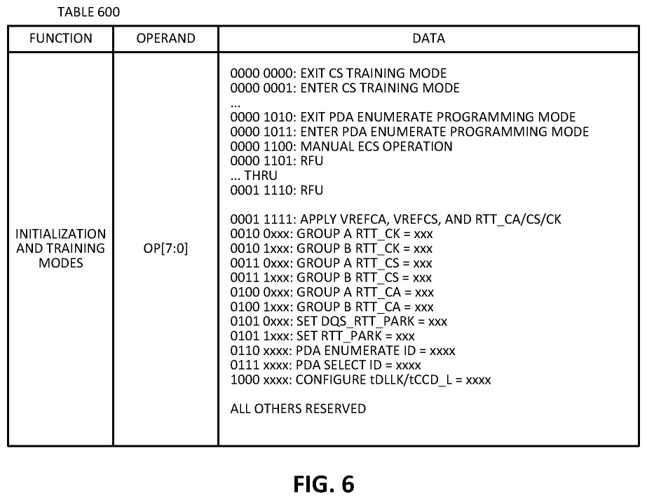

FIG. 6 is an example of a table for an MRUPD mode that also uses M3C. Table 600 describes an application of Option 3 for an implementation of MRUPD. Table 600 includes a function of initialization and training modes, based on OP[7:0]. The data column describes different modes. Selected modes are illustrated, while other modes are left out.

Opcode “0000 0000” indicates exit from CS training mode (CSTM).

Opcode “0000 0001” indicates enter CSTM.

Opcode “0000 1010” indicates exit from per device addressability (PDA) enumerate programming mode.

Opcode “0000 1011” indicates enter PDA enumerate programming mode.

In one example, opcodes “0000 1010” and “0000 1011” can be removed as unneeded.

Opcode “0000 1100” indicates manual error checking and scrub (ECS) operation.

Opcodes “0000 1101” through “0001 1110” represent opcodes reserved for future use (RFU).

Option 3 applies MPC, M3C, and MRUPD. In such an architecture, MPC can be used enter and exit MRUPD. The system can use MRUPD for sweeping the DRAM mode registers (MRs). M3C can be used for initialization such as terminations, device ID, and so forth, as well as for debug and validation.

In one example, Option 3 could utilize opcodes “0001 1111” through “0110 xxxx” for MRUPD/M3C command (CMD) operation.

Opcode “0001 1111” can trigger application of VrefCA, VrefCS, and internal resistance (RTT), including CA signal resistance (RTT_CA), chip select signal resistance (RTT_CS), and clock signal resistance (RTT_CK).

Opcodes “0010 0xxx” can be Group A RTT_CK signals, setting the termination to ‘xxx’.

Opcodes “0010 1xxx” can be Group B RTT_CK signals, setting the termination to ‘xxx’.

Opcodes “0011 0xxx” can be Group A RTT_CS signals, setting the termination to ‘xxx’.

Opcodes “0011 1xxx” can be Group B RTT_CS signals, setting the termination to ‘xxx’.

Opcodes “0100 0xxx” can be Group A RTT_CA signals, setting the termination to ‘xxx’.

Opcodes “0100 1xxx” can be Group B RTT_CA signals, setting the termination to ‘xxx’.

Opcodes “0101 0xxx” can be used to set the data strobe (DQS) park termination, DQS_RTT_PARK, to ‘xxx’.

Opcodes “0101 1xxx” can be used to set the other park terminations, RTT_PARK, to ‘xxx’.

Opcodes “0110 xxxx” can be used to indicate PDA enumerate ID (setting the value to ‘xxxx’).

Opcodes “0111 xxxx” can be used to indicate PDA select ID (setting the value to ‘xxxx’).

Opcodes “1000 xxxx” can be used to configure the delay lock loop timing (tDLLK) and the time required between column to column commands (tCCD)L) (setting the value to ‘xxxx’).

The other opcode encodings can be reserved.

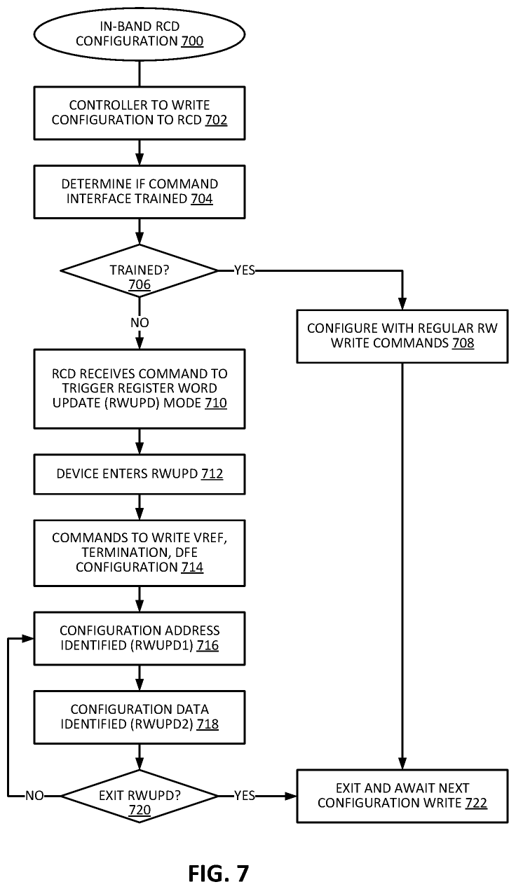

FIG. 7 is a flow diagram of an example of a process for RWUPD. Process 700 represents a process flow for in-band RCD configuration. In one example, the memory controller is to write configuration to the RCD, at 702. The controller can determine if the command interface is trained, at 704.

If the interface is already trained, at 706 YES branch, the system can configure the RCD with regular RW write commands, at 708. If the interface is not already trained, at 706 NO branch, the RCD can receive a command to trigger register word update (RWUPD) mode, at 710. For example, the system can trigger entry into RWUPD with one or more SMBus commands.

The RCD enters RWUPD, at 712, and receives in-band commands to write Vref configuration, termination configuration, or DFE configuration, or a combination of these, at 714. The controller can send all the RWUPD settings, which the RCD writes into the register.

The system can identify configuration address identification, such as with an RWUPD1 command, at 716. The system can identify configuration data, such as with an RWUPD2 command, at 718. The system can continue to update configuration settings until an RWUPD exit command. Thus, if there is no RWUPD exit, at 720 NO branch, the configuration updates can continue at 716.

In response to an RWUPD exit, at 720 YES branch, the RCD can exit RWUPD and await the next configuration write event, at 722. After configuration with regular RW write commands, at 708, the system can also exit configuration mode and await the next configuration write event, at 722.

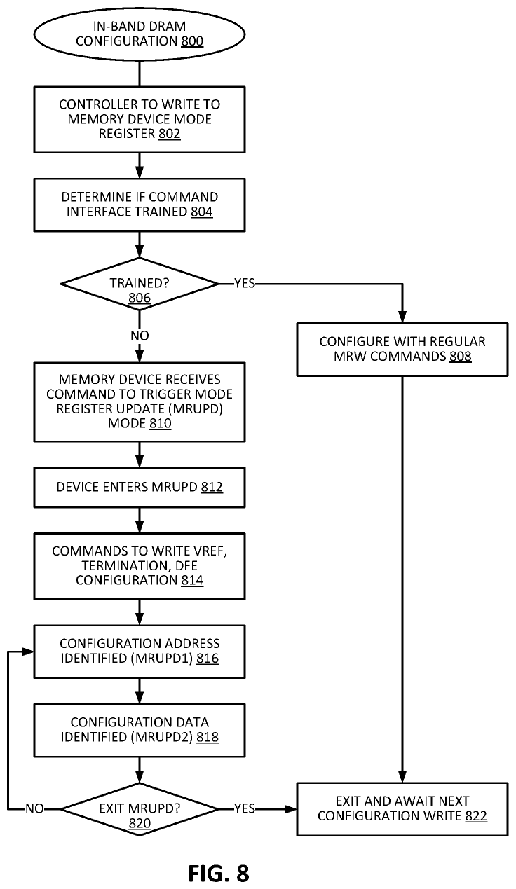

FIG. 8 is a flow diagram of an example of a process for MRUPD. Process 800 represents a process flow for in-band DRAM configuration. In one example, the memory controller is to write configuration to the DRAM, at 802. The controller can determine if the command interface of the DRAM is trained, at 804.

If the interface is already trained, at 806 YES branch, the system can configure the DRAM with regular mode register write (MRW) commands, at 808. If the interface is not already trained, at 806 NO branch, the RCD can receive a command to trigger mode register update (MRUPD) mode, at 810.

The device enters MRUPD, at 812, and receives in-band commands to write Vref configuration, termination configuration, or DFE configuration, or a combination of these, at 814. The controller can send all the MRUPD settings, which the DRAM writes into the register.

The system can identify configuration address identification, such as with an MRUPD1 command, at 816. The system can identify configuration data, such as with an MRUPD2 command, at 818. The system can continue to update configuration settings until an MRUPD exit command. Thus, if there is no MRUPD exit, at 820 NO branch, the configuration updates can continue at 816.

In response to an MRUPD exit, at 820 YES branch, the DRAM can exit MRUPD and await the next configuration write event, at 822. After configuration with regular RW write commands, at 808, the system can also exit configuration mode and await the next configuration write event, at 822.

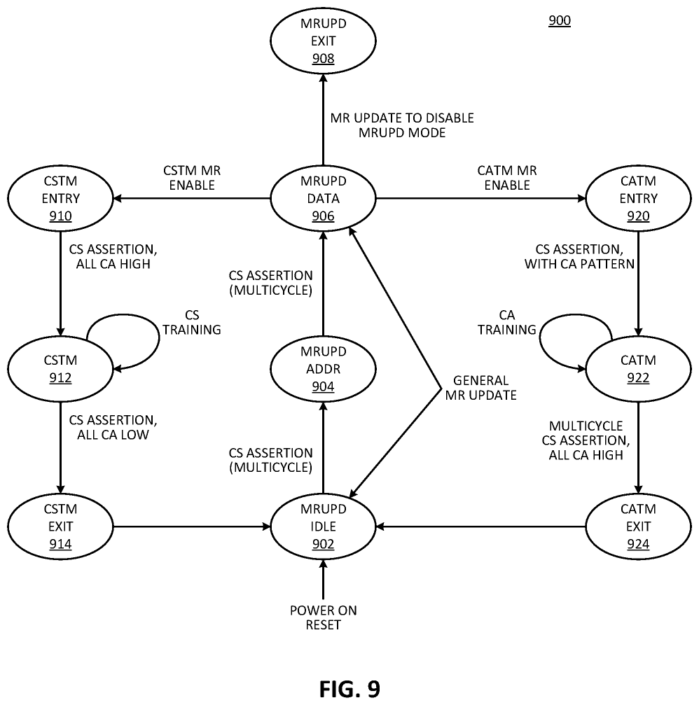

FIG. 9 is a state diagram of an example of MRUPD. System 900 represents various states in an example MRUPD flow. In one example, in response to a power on reset, the memory enters state MRUPD idle 902, which is a state in which the memory can perform in-band training with MRUPD, but is idle in that it does not currently have any operations to perform.

In one example, as an alternative to entering MRUPD idle on power on reset, during debug time, commands on the M3C bus (which can be a subset of I3C basic)

In one example, with a multicycle chip select (CS) assertion, the memory can move to state MRUPD ADDR 904. In response to a CS assertion, the selected memory device can check for an MRUPD address for a configuration update. With another CS assertion, which can also be a multicycle assertion, the memory moves to state MRUPD data 906, in which the memory device acquires the data to write to the address of the previous state.

In one example, the mode register update written can be an update that disables MRUPD mode. In response to such an update, the memory can enter state MRUPD exit 908, and exit from MRUPD mode.

In one example, 902 and 906 can represent states for general mode register updates. Such general updates are not necessarily associated with enabling a training mode. For example, the update can be used for Vref configuration. If Vref is swept outside its range, in one example, the system can use the M3C bus to recover.

In one example, MRUPD data 906 can trigger CSTM entry 910 with a mode register configuration write to enable CSTM. In one example, with a CS assertion with all CA pins set high (e.g., to a high logic state), the memory enters state CSTM 912, to perform chip select training. In one example, during the CS training, the CA pins can be held high. In one example, during CSTM, no commands are supported. Alternatively, the DRAM device can be disabled from decoding any commands.

In one example, in response to a CS assertion with all CA pins driven low, the memory can move to state CSTM exit 914. In response to exiting the CSTM mode, the memory can return to state MRUPD idle 902.

In one example, MRUPD data 906 can trigger CATM entry 920 with a mode register configuration write to enable CATM. In one example, with a CS assertion with a proper CA pattern on the CA pins (e.g., CA encoding or a CATM command), the memory enters state CATM 922, to perform CA bus training. In one example, during the CA bus training, the CA pins can be held at the CA encoding that triggers entry into CATM.

In one example, in response to a multicycle CS assertion with all CA pins driven high, the memory can move to state CATM exit 924. In response to exiting the CATM mode, the memory can return to state MRUPD idle 902.

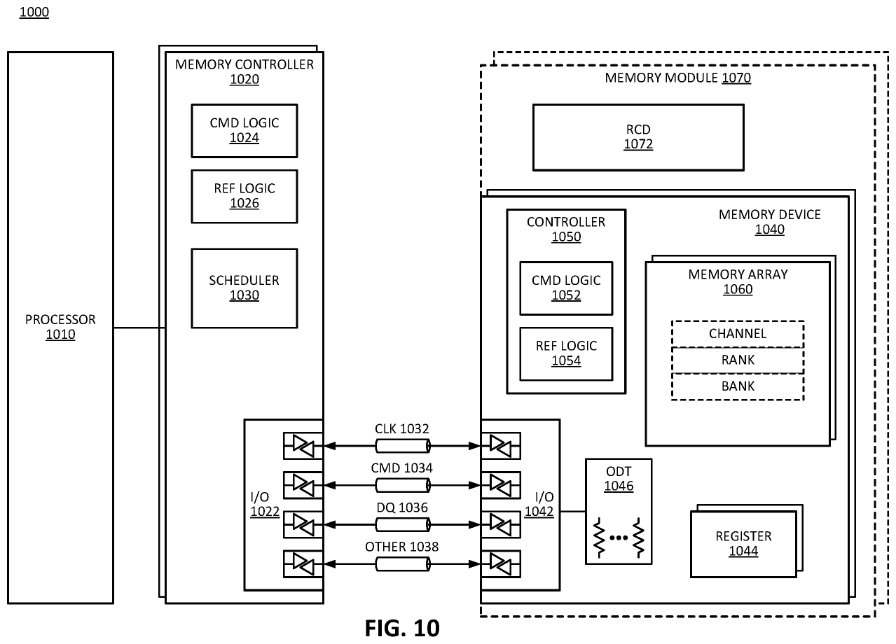

FIG. 10 is a block diagram of an example of a memory subsystem in which an in-band configuration mode can be implemented. System 1000 includes a processor and elements of a memory subsystem in a computing device. System 1000 represents a system with a memory subsystem in accordance with an example of system 100 or an example of system 200 or an example of system 300.

In one example, system 1000 includes RCD 1072 in memory module 1070. RCD 1072 can have its configuration programmed with in-band register writes in accordance with any description herein. Memory device 1040 can represent a DRAM device, which can have its configuration programmed with in-band register writes in accordance with any description herein.

Processor 1010 represents a processing unit of a computing platform that may execute an operating system (OS) and applications, which can collectively be referred to as the host or the user of the memory. The OS and applications execute operations that result in memory accesses. Processor 1010 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory accesses may also be initiated by devices such as a network controller or hard disk controller. Such devices can be integrated with the processor in some systems or attached to the processer via a bus (e.g., PCI express), or a combination. System 1000 can be implemented as an SOC (system on a chip), or be implemented with standalone components.

Reference to memory devices can apply to different memory types. Memory devices often refers to volatile memory technologies. Volatile memory is memory whose state (and therefore the data stored on it) is indeterminate if power is interrupted to the device. Nonvolatile memory refers to memory whose state is determinate even if power is interrupted to the device. Dynamic volatile memory requires refreshing the data stored in the device to maintain state. One example of dynamic volatile memory includes DRAM (dynamic random-access memory), or some variant such as synchronous DRAM (SDRAM). A memory subsystem as described herein may be compatible with a number of memory technologies, such as DDR4 (double data rate version 4, JESD79-4, originally published in September 2012 by JEDEC (Joint Electron Device Engineering Council, now the JEDEC Solid State Technology Association), LPDDR4 (low power DDR version 4, JESD209-4, originally published by JEDEC in August 2014), WI02 (Wide I/O 2 (WideIO2), JESD229-2, originally published by JEDEC in August 2014), HBM (high bandwidth memory DRAM, JESD235A, originally published by JEDEC in November 2015), DDR5 (DDR version 5, originally published by JEDEC in July 2020), LPDDR5 (LPDDR version 5, JESD209-5, originally published by JEDEC in February 2019), HBM2 (HBM version 2, JESD235C, originally published by JEDEC in January 2020), HBM3 (HBM version 3, JESD238, originally published by JEDEC in January 2022), DDR6 (DDR version 6, in discussion), GDDR7 (graphics DDR version 7, in discussion), or others or combinations of memory technologies, and technologies based on derivatives or extensions of such specifications.

Memory controller 1020 represents one or more memory controller circuits or devices for system 1000. In one example, memory controller 1020 is on the same semiconductor substrate as processor 1010. Memory controller 1020 represents control logic that generates memory access commands in response to the execution of operations by processor 1010. Memory controller 1020 accesses one or more memory devices 1040. Memory devices 1040 can be DRAM devices in accordance with any referred to above. In one example, memory devices 1040 are organized and managed as different channels, where each channel couples to buses and signal lines that couple to multiple memory devices in parallel. Each channel is independently operable. Thus, each channel is independently accessed and controlled, and the timing, data transfer, command and address exchanges, and other operations are separate for each channel. Coupling can refer to an electrical coupling, communicative coupling, physical coupling, or a combination of these. Physical coupling can include direct contact. Electrical coupling includes an interface or interconnection that allows electrical flow between components, or allows signaling between components, or both. Communicative coupling includes connections, including wired or wireless, that enable components to exchange data.

In one example, settings for each channel are controlled by separate mode registers or other register settings. In one example, each memory controller 1020 manages a separate memory channel, although system 1000 can be configured to have multiple channels managed by a single controller, or to have multiple controllers on a single channel. In one example, memory controller 1020 is part of host processor 1010, such as logic implemented on the same die or implemented in the same package space as the processor.

Memory controller 1020 includes I/O interface logic 1022 to couple to a memory bus, such as a memory channel as referred to above. I/O interface logic 1022 (as well as I/O interface logic 1042 of memory device 1040) can include pins, pads, connectors, signal lines, traces, or wires, or other hardware to connect the devices, or a combination of these. I/O interface logic 1022 can include a hardware interface. As illustrated, I/O interface logic 1022 includes at least drivers/transceivers for signal lines. Commonly, wires within an integrated circuit interface couple with a pad, pin, or connector to interface signal lines or traces or other wires between devices. I/O interface logic 1022 can include drivers, receivers, transceivers, or termination, or other circuitry or combinations of circuitry to exchange signals on the signal lines between the devices. The exchange of signals includes at least one of transmit or receive. While shown as coupling I/O 1022 from memory controller 1020 to I/O 1042 of memory device 1040, it will be understood that in an implementation of system 1000 where groups of memory devices 1040 are accessed in parallel, multiple memory devices can include I/O interfaces to the same interface of memory controller 1020. In an implementation of system 1000 including one or more memory modules 1070, I/O 1042 can include interface hardware of the memory module in addition to interface hardware on the memory device itself. Other memory controllers 1020 will include separate interfaces to other memory devices 1040.

The bus between memory controller 1020 and memory devices 1040 can be implemented as multiple signal lines coupling memory controller 1020 to memory devices 1040. The bus may typically include at least clock (CLK) 1032, command/address (CMD) 1034, data (DQ) 1036, and zero or more other signal lines 1038. In one example, a bus or connection between memory controller 1020 and memory can be referred to as a memory bus. In one example, the memory bus is a multi-drop bus. The signal lines for CMD can be referred to as a “C/A bus” (or ADD/CMD bus, or some other designation indicating the transfer of commands (C or CMD) and address (A or ADD) information) and the signal lines for write and read DQ can be referred to as a “data bus.” In one example, independent channels have different clock signals, C/A buses, data buses, and other signal lines. Thus, system 1000 can be considered to have multiple “buses,” in the sense that an independent interface path can be considered a separate bus. It will be understood that in addition to the lines explicitly shown, a bus can include at least one of strobe signaling lines, alert lines, auxiliary lines, or other signal lines, or a combination. It will also be understood that serial bus technologies can be used for the connection between memory controller 1020 and memory devices 1040. An example of a serial bus technology is 8B10B encoding and transmission of high-speed data with embedded clock over a single differential pair of signals in each direction. In one example, CMD 1034 represents signal lines shared in parallel with multiple memory devices. In one example, multiple memory devices share encoding command signal lines of CMD 1034, and each has a separate chip select (CS_n) signal line to select individual memory devices.

It will be understood that in the example of system 1000, the bus between memory controller 1020 and memory devices 1040 includes a subsidiary command bus CMD 1034 and a subsidiary bus to carry the write and read data, DQ 1036. In one example, the data bus can include bidirectional lines for read data and for write/command data. In another example, the subsidiary bus DQ 1036 can include unidirectional write signal lines for write and data from the host to memory, and can include unidirectional lines for read data from the memory to the host. In accordance with the chosen memory technology and system design, other signals 1038 may accompany a bus or sub bus, such as strobe lines DQS. Based on design of system 1000, or implementation if a design supports multiple implementations, the data bus can have more or less bandwidth per memory device 1040. For example, the data bus can support memory devices that have either a x4 interface, a x8 interface, a x16 interface, or other interface. The convention “xW,” where W is an integer that refers to an interface size or width of the interface of memory device 1040, which represents a number of signal lines to exchange data with memory controller 1020. The interface size of the memory devices is a controlling factor on how many memory devices can be used concurrently per channel in system 1000 or coupled in parallel to the same signal lines. In one example, high bandwidth memory devices, wide interface devices, or stacked memory configurations, or combinations, can enable wider interfaces, such as a x128 interface, a x256 interface, a x512 interface, a x1024 interface, or other data bus interface width.

In one example, memory devices 1040 and memory controller 1020 exchange data over the data bus in a burst, or a sequence of consecutive data transfers. The burst corresponds to a number of transfer cycles, which is related to a bus frequency. In one example, the transfer cycle can be a whole clock cycle for transfers occurring on a same clock or strobe signal edge (e.g., on the rising edge). In one example, every clock cycle, referring to a cycle of the system clock, is separated into multiple unit intervals (UIs), where each UI is a transfer cycle. For example, double data rate transfers trigger on both edges of the clock signal (e.g., rising and falling). A burst can last for a configured number of UIs, which can be a configuration stored in a register, or triggered on the fly. For example, a sequence of eight consecutive transfer periods can be considered a burst length eight (BL8), and each memory device 1040 can transfer data on each UI. Thus, a x8 memory device operating on BL8 can transfer 64 bits of data (8 data signal lines times 8 data bits transferred per line over the burst). It will be understood that this simple example is merely an illustration and is not limiting.

Memory devices 1040 represent memory resources for system 1000. In one example, each memory device 1040 is a separate memory die. In one example, each memory device 1040 can interface with multiple (e.g., 2) channels per device or die. Each memory device 1040 includes I/O interface logic 1042, which has a bandwidth determined by the implementation of the device (e.g., x16 or x8 or some other interface bandwidth). I/O interface logic 1042 enables the memory devices to interface with memory controller 1020. I/O interface logic 1042 can include a hardware interface, and can be in accordance with I/O 1022 of memory controller, but at the memory device end. In one example, multiple memory devices 1040 are connected in parallel to the same command and data buses. In another example, multiple memory devices 1040 are connected in parallel to the same command bus, and are connected to different data buses. For example, system 1000 can be configured with multiple memory devices 1040 coupled in parallel, with each memory device responding to a command, and accessing memory resources 1060 internal to each. For a Write operation, an individual memory device 1040 can write a portion of the overall data word, and for a Read operation, an individual memory device 1040 can fetch a portion of the overall data word. The remaining bits of the word will be provided or received by other memory devices in parallel.

In one example, memory devices 1040 are disposed directly on a motherboard or host system platform (e.g., a PCB (printed circuit board) or substrate on which processor 1010 is disposed) of a computing device. In one example, memory devices 1040 can be organized into memory modules 1070. In one example, memory modules 1070 represent dual inline memory modules (DIMMs). In one example, memory modules 1070 represent other organization of multiple memory devices to share at least a portion of access or control circuitry, which can be a separate circuit, a separate device, or a separate board from the host system platform. Memory modules 1070 can include multiple memory devices 1040, and the memory modules can include support for multiple separate channels to the included memory devices disposed on them. In another example, memory devices 1040 may be incorporated into the same package as memory controller 1020, such as by techniques such as multi-chip-module (MCM), package-on-package, through-silicon via (TSV), or other techniques or combinations. Similarly, in one example, multiple memory devices 1040 may be incorporated into memory modules 1070, which themselves may be incorporated into the same package as memory controller 1020. It will be appreciated that for these and other implementations, memory controller 1020 may be part of host processor 1010.

Memory devices 1040 each include one or more memory arrays 1060. Memory array 1060 represents addressable memory locations or storage locations for data. Typically, memory array 1060 is managed as rows of data, accessed via wordline (rows) and bitline (individual bits within a row) control. Memory array 1060 can be organized as separate channels, ranks, and banks of memory. Channels may refer to independent control paths to storage locations within memory devices 1040. Ranks may refer to common locations across multiple memory devices (e.g., same row addresses within different devices) in parallel. Banks may refer to sub-arrays of memory locations within a memory device 1040. In one example, banks of memory are divided into sub-banks with at least a portion of shared circuitry (e.g., drivers, signal lines, control logic) for the sub-banks, allowing separate addressing and access. It will be understood that channels, ranks, banks, sub-banks, bank groups, or other organizations of the memory locations, and combinations of the organizations, can overlap in their application to physical resources. For example, the same physical memory locations can be accessed over a specific channel as a specific bank, which can also belong to a rank. Thus, the organization of memory resources will be understood in an inclusive, rather than exclusive, manner.

In one example, memory devices 1040 include one or more registers 1044. Register 1044 represents one or more storage devices or storage locations that provide configuration or settings for the operation of the memory device. In one example, register 1044 can provide a storage location for memory device 1040 to store data for access by memory controller 1020 as part of a control or management operation. In one example, register 1044 includes one or more Mode Registers. In one example, register 1044 includes one or more multipurpose registers. The configuration of locations within register 1044 can configure memory device 1040 to operate in different “modes,” where command information can trigger different operations within memory device 1040 based on the mode. Additionally or in the alternative, different modes can also trigger different operation from address information or other signal lines depending on the mode. Settings of register 1044 can indicate configuration for I/O settings (e.g., timing, termination or ODT (on-die termination) 1046, driver configuration, or other I/O settings).

In one example, memory device 1040 includes ODT 1046 as part of the interface hardware associated with I/O 1042. ODT 1046 can be configured as mentioned above, and provide settings for impedance to be applied to the interface to specified signal lines. In one example, ODT 1046 is applied to DQ signal lines. In one example, ODT 1046 is applied to command signal lines. In one example, ODT 1046 is applied to address signal lines. In one example, ODT 1046 can be applied to any combination of the preceding. The ODT settings can be changed based on whether a memory device is a selected target of an access operation or a non-target device. ODT 1046 settings can affect the timing and reflections of signaling on the terminated lines. Careful control over ODT 1046 can enable higher-speed operation with improved matching of applied impedance and loading. ODT 1046 can be applied to specific signal lines of I/O interface 1042, 1022 (for example, ODT for DQ lines or ODT for CA lines), and is not necessarily applied to all signal lines.

Memory device 1040 includes controller 1050, which represents control logic within the memory device to control internal operations within the memory device. For example, controller 1050 decodes commands sent by memory controller 1020 and generates internal operations to execute or satisfy the commands. Controller 1050 can be referred to as an internal controller, and is separate from memory controller 1020 of the host. Controller 1050 can determine what mode is selected based on register 1044, and configure the internal execution of operations for access to memory resources 1060 or other operations based on the selected mode. Controller 1050 generates control signals to control the routing of bits within memory device 1040 to provide a proper interface for the selected mode and direct a command to the proper memory locations or addresses. Controller 1050 includes command logic 1052, which can decode command encoding received on command and address signal lines. Thus, command logic 1052 can be or include a command decoder. With command logic 1052, memory device can identify commands and generate internal operations to execute requested commands.

Referring again to memory controller 1020, memory controller 1020 includes command (CMD) logic 1024, which represents logic or circuitry to generate commands to send to memory devices 1040. The generation of the commands can refer to the command prior to scheduling, or the preparation of queued commands ready to be sent. Generally, the signaling in memory subsystems includes address information within or accompanying the command to indicate or select one or more memory locations where the memory devices should execute the command. In response to scheduling of transactions for memory device 1040, memory controller 1020 can issue commands via I/O 1022 to cause memory device 1040 to execute the commands. In one example, controller 1050 of memory device 1040 receives and decodes command and address information received via I/O 1042 from memory controller 1020. Based on the received command and address information, controller 1050 can control the timing of operations of the logic and circuitry within memory device 1040 to execute the commands. Controller 1050 is responsible for compliance with standards or specifications within memory device 1040, such as timing and signaling requirements. Memory controller 1020 can implement compliance with standards or specifications by access scheduling and control.

Memory controller 1020 includes scheduler 1030, which represents logic or circuitry to generate and order transactions to send to memory device 1040. From one perspective, the primary function of memory controller 1020 could be said to schedule memory access and other transactions to memory device 1040. Such scheduling can include generating the transactions themselves to implement the requests for data by processor 1010 and to maintain integrity of the data (e.g., such as with commands related to refresh). Transactions can include one or more commands, and result in the transfer of commands or data or both over one or multiple timing cycles such as clock cycles or unit intervals. Transactions can be for access such as read or write or related commands or a combination, and other transactions can include memory management commands for configuration, settings, data integrity, or other commands or a combination.

Memory controller 1020 typically includes logic such as scheduler 1030 to allow selection and ordering of transactions to improve performance of system 1000. Thus, memory controller 1020 can select which of the outstanding transactions should be sent to memory device 1040 in which order, which is typically achieved with logic much more complex that a simple first-in first-out algorithm. Memory controller 1020 manages the transmission of the transactions to memory device 1040, and manages the timing associated with the transaction. In one example, transactions have deterministic timing, which can be managed by memory controller 1020 and used in determining how to schedule the transactions with scheduler 1030.

In one example, memory controller 1020 includes refresh (REF) logic 1026. Refresh logic 1026 can be used for memory resources that are volatile and need to be refreshed to retain a deterministic state. In one example, refresh logic 1026 indicates a location for refresh, and a type of refresh to perform. Refresh logic 1026 can trigger self-refresh within memory device 1040, or execute external refreshes which can be referred to as auto refresh commands) by sending refresh commands, or a combination. In one example, controller 1050 within memory device 1040 includes refresh logic 1054 to apply refresh within memory device 1040. In one example, refresh logic 1054 generates internal operations to perform refresh in accordance with an external refresh received from memory controller 1020. Refresh logic 1054 can determine if a refresh is directed to memory device 1040, and what memory resources 1060 to refresh in response to the command.

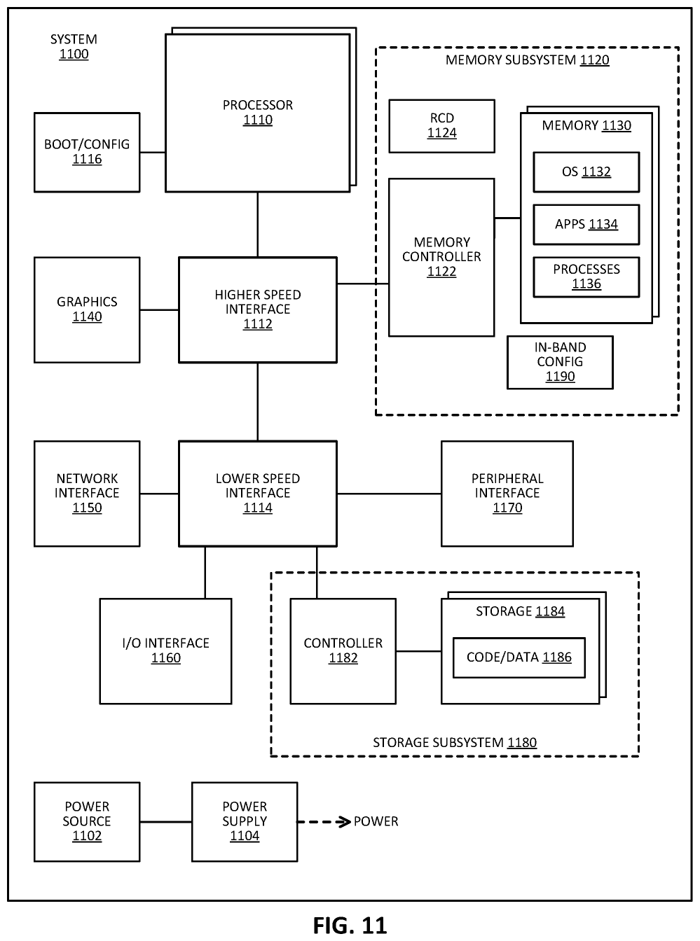

FIG. 11 is a block diagram of an example of a computing system in which in-band configuration mode can be implemented. System 1100 represents a computing device in accordance with any example herein, and can be a laptop computer, a desktop computer, a tablet computer, a server, a gaming or entertainment control system, embedded computing device, or other electronic device. System 1100 represents a system with storage in accordance with an example of system 100 or an example of system 200 or an example of system 300.

In one example, system 1100 includes memory subsystem 1120, with RCD 1124 in a memory module. RCD 1124 can have its configuration programmed with in-band register writes in accordance with any description herein. Memory 1130 can represent a DRAM device, which can have its configuration programmed with in-band register writes in accordance with any description herein. In-band configuration (CONFIG) 1190 represents the components that enable system to perform in-band register configuration updates with an update mode.

System 1100 includes processor 1110 can include any type of microprocessor, central processing unit (CPU), graphics processing unit (GPU), processing core, or other processing hardware, or a combination, to provide processing or execution of instructions for system 1100. Processor 1110 can be a host processor device. Processor 1110 controls the overall operation of system 1100, and can be or include, one or more programmable general-purpose or special-purpose microprocessors, digital signal processors (DSPs), programmable controllers, application specific integrated circuits (ASICs), programmable logic devices (PLDs), or a combination of such devices.

System 1100 includes boot/config 1116, which represents storage to store boot code (e.g., basic input/output system (BIOS)), configuration settings, security hardware (e.g., trusted platform module (TPM)), or other system level hardware that operates outside of a host OS. Boot/config 1116 can include a nonvolatile storage device, such as read-only memory (ROM), flash memory, or other memory devices.

In one example, system 1100 includes interface 1112 coupled to processor 1110, which can represent a higher speed interface or a high throughput interface for system components that need higher bandwidth connections, such as memory subsystem 1120 or graphics interface components 1140. Interface 1112 represents an interface circuit, which can be a standalone component or integrated onto a processor die. Interface 1112 can be integrated as a circuit onto the processor die or integrated as a component on a system on a chip. Where present, graphics interface 1140 interfaces to graphics components for providing a visual display to a user of system 1100. Graphics interface 1140 can be a standalone component or integrated onto the processor die or system on a chip. In one example, graphics interface 1140 can drive a high definition (HD) display or ultra high definition (UHD) display that provides an output to a user. In one example, the display can include a touchscreen display. In one example, graphics interface 1140 generates a display based on data stored in memory 1130 or based on operations executed by processor 1110 or both.

Memory subsystem 1120 represents the main memory of system 1100, and provides storage for code to be executed by processor 1110, or data values to be used in executing a routine. Memory subsystem 1120 can include one or more varieties of random-access memory (RAM) such as DRAM, 3DXP (three-dimensional crosspoint), or other memory devices, or a combination of such devices. Memory 1130 stores and hosts, among other things, operating system (OS) 1132 to provide a software platform for execution of instructions in system 1100. Additionally, applications 1134 can execute on the software platform of OS 1132 from memory 1130. Applications 1134 represent programs that have their own operational logic to perform execution of one or more functions. Processes 1136 represent agents or routines that provide auxiliary functions to OS 1132 or one or more applications 1134 or a combination. OS 1132, applications 1134, and processes 1136 provide software logic to provide functions for system 1100. In one example, memory subsystem 1120 includes memory controller 1122, which is a memory controller to generate and issue commands to memory 1130. It will be understood that memory controller 1122 could be a physical part of processor 1110 or a physical part of interface 1112. For example, memory controller 1122 can be an integrated memory controller, integrated onto a circuit with processor 1110, such as integrated onto the processor die or a system on a chip.

While not specifically illustrated, it will be understood that system 1100 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or other bus, or a combination.

In one example, system 1100 includes interface 1114, which can be coupled to interface 1112. Interface 1114 can be a lower speed interface than interface 1112. In one example, interface 1114 represents an interface circuit, which can include standalone components and integrated circuitry. In one example, multiple user interface components or peripheral components, or both, couple to interface 1114. Network interface 1150 provides system 1100 the ability to communicate with remote devices (e.g., servers or other computing devices) over one or more networks. Network interface 1150 can include an Ethernet adapter, wireless interconnection components, cellular network interconnection components, USB (universal serial bus), or other wired or wireless standards-based or proprietary interfaces. Network interface 1150 can exchange data with a remote device, which can include sending data stored in memory or receiving data to be stored in memory.

In one example, system 1100 includes one or more input/output (I/O) interface(s) 1160. I/O interface 1160 can include one or more interface components through which a user interacts with system 1100 (e.g., audio, alphanumeric, tactile/touch, or other interfacing). Peripheral interface 1170 can include any hardware interface not specifically mentioned above. Peripherals refer generally to devices that connect dependently to system 1100. A dependent connection is one where system 1100 provides the software platform or hardware platform or both on which operation executes, and with which a user interacts.

In one example, system 1100 includes storage subsystem 1180 to store data in a nonvolatile manner. In one example, in certain system implementations, at least certain components of storage 1180 can overlap with components of memory subsystem 1120. Storage subsystem 1180 includes storage device(s) 1184, which can be or include any conventional medium for storing large amounts of data in a nonvolatile manner, such as one or more magnetic, solid state, NAND, 3DXP, or optical based disks, or a combination. Storage 1184 holds code or instructions and data 1186 in a persistent state (i.e., the value is retained despite interruption of power to system 1100). Storage 1184 can be generically considered to be a “memory,” although memory 1130 is typically the executing or operating memory to provide instructions to processor 1110. Whereas storage 1184 is nonvolatile, memory 1130 can include volatile memory (i.e., the value or state of the data is indeterminate if power is interrupted to system 1100). In one example, storage subsystem 1180 includes controller 1182 to interface with storage 1184. In one example controller 1182 is a physical part of interface 1114 or processor 1110, or can include circuits or logic in both processor 1110 and interface 1114.

Power source 1102 provides power to the components of system 1100. More specifically, power source 1102 typically interfaces to one or multiple power supplies 1104 in system 1100 to provide power to the components of system 1100. In one example, power supply 1104 includes an AC to DC (alternating current to direct current) adapter to plug into a wall outlet. Such AC power can be renewable energy (e.g., solar power) power source 1102. In one example, power source 1102 includes a DC power source, such as an external AC to DC converter. In one example, power source 1102 or power supply 1104 includes wireless charging hardware to charge via proximity to a charging field. In one example, power source 1102 can include an internal battery or fuel cell source.

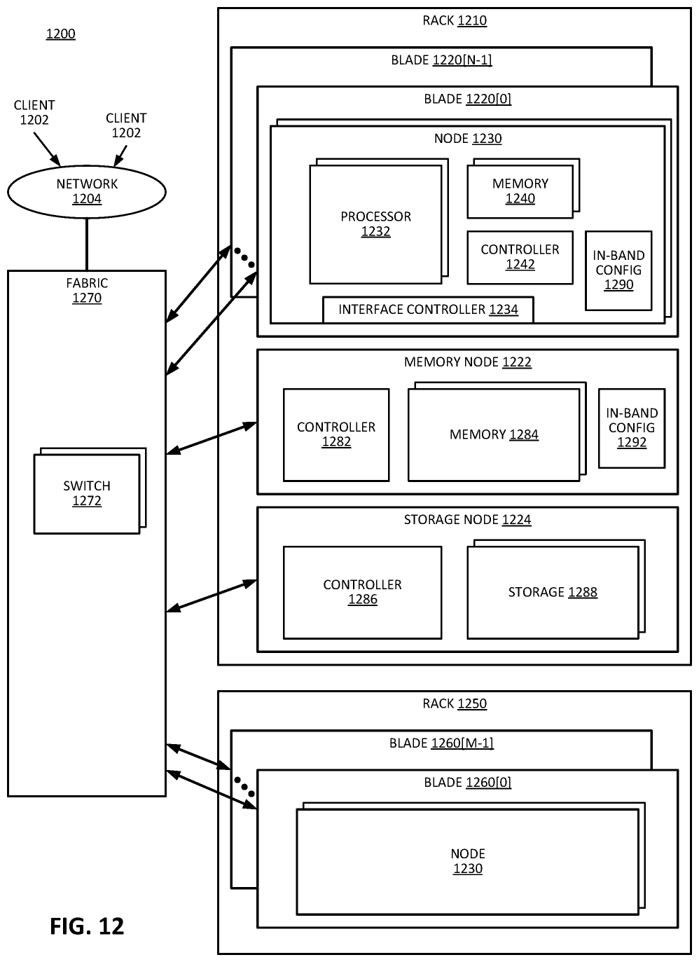

FIG. 12 is a block diagram of an example of a multi-node network in which in-band configuration mode can be implemented. System 1200 represents a network of nodes that can apply adaptive ECC. In one example, system 1200 represents a data center. In one example, system 1200 represents a server farm. In one example, system 1200 represents a data cloud or a processing cloud.

System 1200 represents a system with storage in accordance with an example of system 100 or an example of system 200 or an example of system 300. In one example, memory node 1222 includes memory modules with an RCD (not specifically illustrated). The RCD can have its configuration programmed with in-band register writes in accordance with any description herein, as represented by in-band configuration (CONFIG) 1292. System 1200 can include memory devices in accordance with what is described, and in-band configuration (CONFIG) 1290 represents the ability to use in-band register writes in accordance with any description herein to program an RCD and/or a memory device.

One or more clients 1202 make requests over network 1204 to system 1200.

Network 1204 represents one or more local networks, or wide area networks, or a combination. Clients 1202 can be human or machine clients, which generate requests for the execution of operations by system 1200. System 1200 executes applications or data computation tasks requested by clients 1202.

In one example, system 1200 includes one or more racks, which represent structural and interconnect resources to house and interconnect multiple computation nodes. In one example, rack 1210 includes multiple nodes 1230. In one example, rack 1210 hosts multiple blade components, blade 1220[0], . . . , blade 1220[N−1], collectively blades 1220. Hosting refers to providing power, structural or mechanical support, and interconnection. Blades 1220 can refer to computing resources on printed circuit boards (PCBs), where a PCB houses the hardware components for one or more nodes 1230. In one example, blades 1220 do not include a chassis or housing or other “box” other than that provided by rack 1210. In one example, blades 1220 include housing with exposed connector to connect into rack 1210. In one example, system 1200 does not include rack 1210, and each blade 1220 includes a chassis or housing that can stack or otherwise reside in close proximity to other blades and allow interconnection of nodes 1230.

System 1200 includes fabric 1270, which represents one or more interconnectors for nodes 1230. In one example, fabric 1270 includes multiple switches 1272 or routers or other hardware to route signals among nodes 1230. Additionally, fabric 1270 can couple system 1200 to network 1204 for access by clients 1202. In addition to routing equipment, fabric 1270 can be considered to include the cables or ports or other hardware equipment to couple nodes 1230 together. In one example, fabric 1270 has one or more associated protocols to manage the routing of signals through system 1200. In one example, the protocol or protocols is at least partly dependent on the hardware equipment used in system 1200.

As illustrated, rack 1210 includes N blades 1220. In one example, in addition to rack 1210, system 1200 includes rack 1250. As illustrated, rack 1250 includes M blade components, blade 1260[0], . . . , blade 1260[M−1], collectively blades 1260. M is not necessarily the same as N; thus, it will be understood that various different hardware equipment components could be used, and coupled together into system 1200 over fabric 1270. Blades 1260 can be the same or similar to blades 1220. Nodes 1230 can be any type of node and are not necessarily all the same type of node. System 1200 is not limited to being homogenous, nor is it limited to not being homogenous.

The nodes in system 1200 can include compute nodes, memory nodes, storage nodes, accelerator nodes, or other nodes. Rack 1210 is represented with memory node 1222 and storage node 1224, which represent shared system memory resources, and shared persistent storage, respectively. One or more nodes of rack 1250 can be a memory node or a storage node.

Nodes 1230 represent examples of compute nodes. For simplicity, only the compute node in blade 1220[0] is illustrated in detail. However, other nodes in system 1200 can be the same or similar. At least some nodes 1230 are computation nodes, with processor (proc) 1232 and memory 1240. A computation node refers to a node with processing resources (e.g., one or more processors) that executes an operating system and can receive and process one or more tasks. In one example, at least some nodes 1230 are server nodes with a server as processing resources represented by processor 1232 and memory 1240.

Memory node 1222 represents an example of a memory node, with system memory external to the compute nodes. Memory nodes can include controller 1282, which represents a processor on the node to manage access to the memory. The memory nodes include memory 1284 as memory resources to be shared among multiple compute nodes.

Storage node 1224 represents an example of a storage server, which refers to a node with more storage resources than a computation node, and rather than having processors for the execution of tasks, a storage server includes processing resources to manage access to the storage nodes within the storage server. Storage nodes can include controller 1286 to manage access to the storage 1288 of the storage node.

In one example, node 1230 includes interface controller 1234, which represents logic to control access by node 1230 to fabric 1270. The logic can include hardware resources to interconnect to the physical interconnection hardware. The logic can include software or firmware logic to manage the interconnection. In one example, interface controller 1234 is or includes a host fabric interface, which can be a fabric interface in accordance with any example described herein. The interface controllers for memory node 1222 and storage node 1224 are not explicitly shown.

Processor 1232 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory 1240 can be or include memory devices represented by memory 1240 and a memory controller represented by controller 1242.

In one aspect, an apparatus includes: a hardware interface to interface with a command bus, the hardware interface to receive a configuration register update mode command to trigger entry into a configuration register update mode; a decision feedback equalization (DFE) configuration register to store a first configuration setting for the hardware interface to the command bus; and a second configuration register for a configuration setting other than DFE, the second configuration register to store a second configuration setting for the hardware interface to the command bus; wherein the apparatus is to update the second configuration register with in-band register writes in the configuration register update mode.

In one example of the apparatus, the in-band register writes avoid use of sideband bus communication to update the second configuration register. In accordance with any preceding example of the apparatus, in one example, the configuration register update mode comprises a training mode for all configuration register training. In accordance with any preceding example of the apparatus, in one example, the configuration register update mode comprises a register word update (RWUPD) mode for a registering clock driver (RCD). In accordance with any preceding example of the apparatus, in one example, the in-band register writes comprise register word (RW) writes based on commands on the command bus, without use of a system management bus (SMBus). In accordance with any preceding example of the apparatus, in one example, the in-band register writes comprise register word (RW) writes based on commands on the command bus, in combination with use of a system management bus (SMBus). In accordance with any preceding example of the apparatus, in one example, the configuration register update mode comprises a mode register update (MRUPD) mode for a dynamic random access memory (DRAM) device. In accordance with any preceding example of the apparatus, in one example, the in-band register writes comprise mode register writes (MRWs) based on commands on the command bus prior to execution of a chip select training mode (CSTM). In accordance with any preceding example of the apparatus, in one example, the in-band register writes comprise mode register writes (MRWs) based on commands on the command bus prior to execution of a command/address training mode (CATM). In accordance with any preceding example of the apparatus, in one example, the in-band register writes avoid use of multipurpose command (MPC) to train the DFE configuration register and the second configuration register. In accordance with any preceding example of the apparatus, in one example, the configuration register update mode command comprises a first multipurpose command (MPC) to enter the configuration register update mode and further comprising a second MPC to exit the configuration register update mode.

In one aspect, a first computer system includes: a memory controller coupled to a command bus; and a memory chip coupled to the command bus with a command bus interface, the memory chip to receive a configuration register update mode command from the memory controller to trigger the memory chip to enter a configuration register update mode, the memory chip including: a decision feedback equalization (DFE) configuration register to store a first configuration setting for the command bus interface; and a second configuration register for a configuration setting other than DFE, the second configuration register to store a second configuration setting for the command bus interface; and wherein the memory chip is to update the second configuration register with in-band register writes in the configuration register update mode.

In one example of the first computer system of claim 12, wherein the in-band register writes avoid use of sideband bus communication to update the second configuration register. In accordance with any preceding example of the first computer system, in one example, the memory chip comprises a registering clock driver (RCD), and wherein the configuration register update mode comprises a register word update (RWUPD) mode for the RCD. In accordance with any preceding example of the first computer system, in one example, the in-band register writes comprise register word (RW) writes based on commands on the command bus, without use of a system management bus (SMBus). In accordance with any preceding example of the first computer system, in one example, the in-band register writes comprise register word (RW) writes based on commands on the command bus, in combination with use of a system management bus (SMBus). In accordance with any preceding example of the first computer system, in one example, the memory chip comprises a dynamic random access memory (DRAM) device, and wherein the configuration register update mode comprises a mode register update (MRUPD) mode for the DRAM device. In accordance with any preceding example of the first computer system, in one example, the in-band register writes comprise mode register writes (MRWs) based on commands on the command bus prior to execution of a chip select training mode (CSTM) and prior to execution of a command/address training mode (CATM). In accordance with any preceding example of the first computer system, in one example, the in-band register writes avoid use of multipurpose command (MPC) to train the DFE configuration register and the second configuration register. In accordance with any preceding example of the first computer system, in one example, the first computer system includes one or more of: a host processor device coupled to the memory controller; a display communicatively coupled to a host processor coupled to the memory controller; a network interface communicatively coupled to a host processor coupled to the memory controller; or a battery to power the computer system.

In one aspect, a first method includes: in a device having a decision feedback equalization (DFE) configuration register to store a first configuration setting for a hardware interface to a command bus and a second configuration register for a configuration setting other than DFE, the second configuration register to store a second configuration setting for the hardware interface to the command bus, receiving a configuration register update mode command to trigger entry into a configuration register update mode; and updating the second configuration register with in-band register writes in the configuration register update mode.

In one example of the first method, the in-band register writes avoid use of sideband bus communication to update the second configuration register. In accordance with any preceding example of the first method, in one example, the configuration register update mode comprises a training mode for all configuration register training. In accordance with any preceding example of the first method, in one example, the configuration register update mode comprises a register word update (RWUPD) mode for a registering clock driver (RCD). In accordance with any preceding example of the first method, in one example, the in-band register writes comprise register word (RW) writes based on commands on the command bus, without use of a system management bus (SMBus). In accordance with any preceding example of the first method, in one example, the in-band register writes comprise register word (RW) writes based on commands on the command bus, in combination with use of a system management bus (SMBus). In accordance with any preceding example of the first method, in one example, the configuration register update mode comprises a mode register update (MRUPD) mode for a dynamic random access memory (DRAM) device. In accordance with any preceding example of the first method, in one example, the in-band register writes comprise mode register writes (MRWs) based on commands on the command bus prior to execution of a chip select training mode (CSTM). In accordance with any preceding example of the first method, in one example, the in-band register writes comprise mode register writes (MRWs) based on commands on the command bus prior to execution of a command/address training mode (CATM). In accordance with any preceding example of the first method, in one example, the in-band register writes avoid use of multipurpose command (MPC) to train the DFE configuration register and the second configuration register. In accordance with any preceding example of the first method, in one example, the configuration register update mode command comprises a first multipurpose command (MPC) to enter the configuration register update mode and further comprising a second MPC to exit the configuration register update mode.

In one aspect, a registering clock driver (RCD) includes: a hardware interface to interface with a command bus, the hardware interface to receive a command to trigger entry into a register word update (RWUPD) mode; and a register word for a configuration setting other than decision feedback equalization (DFE) configuration, the register word to store a configuration setting for the hardware interface to the command bus; wherein the RCD is to update the register word with in-band register writes in the RWUPD mode.

In one example of the RCD, the in-band register writes avoid use of sideband bus communication to update the register word. In accordance with any preceding example of the RCD, in one example, the RWUPD mode comprises a training mode for all configuration of register words. In accordance with any preceding example of the RCD, in one example, the in-band register writes comprise register word (RW) writes based on commands on the command bus, without use of a system management bus (SMBus). In accordance with any preceding example of the RCD, in one example, the in-band register writes comprise register word (RW) writes based on commands on the command bus, in combination with use of a system management bus (SMBus).

In one aspect, a second computer system includes: a memory controller coupled to a command bus; and a dual inline memory module (DIMM) have a registering clock driver (RCD) coupled to the command bus with a command bus interface, the RCD to receive a command to trigger entry into a register word update (RWUPD) mode, the RCD including: a register word for a configuration setting other than decision feedback equalization (DFE) configuration, the register word to store a configuration setting for a hardware interface to the command bus; wherein the RCD is to update the register word with in-band register writes in the RWUPD mode.

In one example of the second computer system, the in-band register writes avoid use of sideband bus communication to update the register word. In accordance with any preceding example of the second computer system, in one example, the in-band register writes comprise register word (RW) writes based on commands on the command bus, without use of a system management bus (SMBus). In accordance with any preceding example of the second computer system, in one example, the in-band register writes comprise register word (RW) writes based on commands on the command bus, in combination with use of a system management bus (SMBus). In accordance with any preceding example of the second computer system, in one example, the in-band register writes comprise mode register writes (MRWs) based on commands on the command bus prior to execution of a chip select training mode (CSTM) and prior to execution of a command/address training mode (CATM). In accordance with any preceding example of the second computer system, in one example, the in-band register writes avoid use of multipurpose command (MPC) to configure the register word. In accordance with any preceding example of the second computer system, in one example, the second computer system includes one or more of: a host processor device coupled to the memory controller; a display communicatively coupled to a host processor coupled to the memory controller; a network interface communicatively coupled to a host processor coupled to the memory controller; or a battery to power the computer system.

In one aspect, a second method includes: in a registering clock driver (RCD) having a configuration register to store a second configuration setting other than decision feedback equalization (DFE) for a hardware interface to a command bus, receiving a command to trigger entry into a register word update (RWUPD) mode; and updating the register word with in-band register writes in the RWUPD mode.

In one example of the second method, the in-band register writes avoid use of sideband bus communication to update the register word. In accordance with any preceding example of the second method, in one example, the RWUPD mode comprises a training mode for all register word configuration. In accordance with any preceding example of the second method, in one example, the in-band register writes comprise register word (RW) writes based on commands on the command bus, without use of a system management bus (SMBus). In accordance with any preceding example of the second method, in one example, the in-band register writes comprise register word (RW) writes based on commands on the command bus, in combination with use of a system management bus (SMBus).

In one aspect, a dynamic random access memory (DRAM) device includes: a hardware interface to interface with a command bus, the hardware interface to receive a command to trigger entry into a mode register update (MRUPD) mode; and a mode register for a configuration setting other than decision feedback equalization (DFE) configuration, the mode register to store a configuration setting for the hardware interface to the command bus; wherein the DRAM device is to update the mode register with in-band register writes in the MRUPD mode.

In one example of the DRAM, the in-band register writes avoid use of sideband bus communication to update the mode register. In accordance with any preceding example of the DRAM, in one example, the MRUPD mode comprises a training mode for all mode register configuration. In accordance with any preceding example of the DRAM, in one example, the in-band register writes comprise mode register writes (MRWs) based on commands on the command bus, without use of a sideband bus. In accordance with any preceding example of the DRAM, in one example, the sideband bus comprises a memory module management control (M3C) bus. In accordance with any preceding example of the DRAM, in one example, the in-band register writes comprise mode register writes (MRWs) based on commands on the command bus, in combination with use of a sideband bus. In accordance with any preceding example of the DRAM, in one example, the sideband bus comprises a memory module management control (M3C) bus. In accordance with any preceding example of the DRAM, in one example, the in-band register writes comprise mode register writes (MRWs) based on commands on the command bus prior to execution of a chip select training mode (CSTM). In accordance with any preceding example of the DRAM, in one example, the in-band register writes comprise mode register writes (MRWs) based on commands on the command bus prior to execution of a command/address training mode (CATM). In accordance with any preceding example of the DRAM, in one example, the in-band register writes avoid use of multipurpose command (MPC) to configure the mode register. In accordance with any preceding example of the DRAM, in one example, the command comprises a first multipurpose command (MPC) to enter the MRUPD mode and further comprising a second MPC to exit the MRUPD mode.

In one aspect, a third computer system includes: a memory controller coupled to a command bus; and a dynamic random access memory (DRAM) device coupled to the command bus with a command bus interface, the DRAM device to receive a command from the memory controller to trigger entry into a mode register update (MRUPD) mode, the DRAM device including: a mode register for a configuration setting other than decision feedback equalization (DFE) configuration, the mode register to store a configuration setting for a hardware interface to the command bus; wherein the DRAM device is to update the mode register with in-band register writes in the MRUPD mode.

In one example of the third computer system, the in-band register writes avoid use of sideband bus communication to update the mode register. In accordance with any preceding example of the third computer system, in one example, the MRUPD mode comprises a training mode for all mode register configuration. In accordance with any preceding example of the third computer system, in one example, the in-band register writes comprise register word (RW) writes based on commands on the command bus, without use of a sideband bus. In accordance with any preceding example of the third computer system, in one example, the sideband bus comprises a memory module management control (M3C) bus. In accordance with any preceding example of the third computer system, in one example, the in-band register writes comprise mode register writes (MRWs) based on commands on the command bus, in combination with use of a sideband bus. In accordance with any preceding example of the third computer system, in one example, the sideband bus comprises a memory module management control (M3C) bus. In accordance with any preceding example of the third computer system, in one example, the in-band register writes comprise mode register writes (MRWs) based on commands on the command bus prior to execution of a chip select training mode (CSTM). In accordance with any preceding example of the third computer system, in one example, the in-band register writes comprise mode register writes (MRWs) based on commands on the command bus prior to execution of a command/address training mode (CATM). In accordance with any preceding example of the third computer system, in one example, the in-band register writes avoid use of multipurpose command (MPC) to configure the mode register. In accordance with any preceding example of the third computer system, in one example, the command comprises a first multipurpose command (MPC) to enter the MRUPD mode and further comprising a second MPC to exit the MRUPD mode. In accordance with any preceding example of the third computer system, in one example, the third computer system includes one or more of: a host processor device coupled to the memory controller; a display communicatively coupled to a host processor coupled to the memory controller; a network interface communicatively coupled to a host processor coupled to the memory controller; or a battery to power the computer system.

In one aspect, a third method includes: in a dynamic random access memory (DRAM) device having a mode register to store a second configuration setting other than decision feedback equalization (DFE) for a hardware interface to a command bus, receiving a command to trigger entry into a mode register update (MRUPD) mode; and updating the mode register with in-band register writes in the MRUPD mode.

In one example of the third method, the in-band register writes avoid use of sideband bus communication to update the mode register. In accordance with any preceding example of the third method, in one example, the MRUPD mode comprises a training mode for all mode register configuration. In accordance with any preceding example of the third method, in one example, the in-band register writes comprise register word (RW) writes based on commands on the command bus, without use of a sideband bus. In accordance with any preceding example of the third method, in one example, the sideband bus comprises a memory module management control (M3C) bus. In accordance with any preceding example of the third method, in one example, the in-band register writes comprise register word (RW) writes based on commands on the command bus, in combination with use of a sideband bus. In accordance with any preceding example of the third method, in one example, the sideband bus comprises a memory module management control (M3C) bus. In accordance with any preceding example of the third method, in one example, the in-band register writes comprise mode register writes (MRWs) based on commands on the command bus prior to execution of a chip select training mode (CSTM). In accordance with any preceding example of the third method, in one example, the in-band register writes comprise mode register writes (MRWs) based on commands on the command bus prior to execution of a command/address training mode (CATM). In accordance with any preceding example of the third method, in one example, the in-band register writes avoid use of multipurpose command (MPC) to train the mode register. In accordance with any preceding example of the third method, in one example, the command comprises a first multipurpose command (MPC) to enter the MRUPD mode and further comprising a second MPC to exit the MRUPD mode.

Flow diagrams as illustrated herein provide examples of sequences of various process actions. The flow diagrams can indicate operations to be executed by a software or firmware routine, as well as physical operations. A flow diagram can illustrate an example of the implementation of states of a finite state machine (FSM), which can be implemented in hardware and/or software. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted; thus, not all implementations will perform all actions.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. An apparatus, comprising:
a hardware interface to interface with a command bus, the hardware interface to receive a configuration register update mode command to trigger entry into a configuration register update mode;
a decision feedback equalization (DFE) configuration register to store a first configuration setting for the hardware interface to the command bus; and
a second configuration register for a configuration setting other than DFE, the second configuration register to store a second configuration setting for the hardware interface to the command bus;
wherein the apparatus is to update the second configuration register with in-band register writes in the configuration register update mode.

2. The apparatus of claim 1, wherein the in-band register writes avoid use of sideband bus communication to update the second configuration register.

3. The apparatus of claim 1, wherein the configuration register update mode comprises a training mode for all configuration register training.

4. The apparatus of claim 1, wherein the configuration register update mode comprises a register word update (RWUPD) mode for a registering clock driver (RCD).

5. The apparatus of claim 4, wherein the in-band register writes comprise register word (RW) writes based on commands on the command bus, without use of a system management bus (SMBus).

6. The apparatus of claim 4, wherein the in-band register writes comprise register word (RW) writes based on commands on the command bus, in combination with use of a system management bus (SMBus).

7. The apparatus of claim 1, wherein the configuration register update mode comprises a mode register update (MRUPD) mode for a dynamic random access memory (DRAM) device.

8. The apparatus of claim 7, wherein the in-band register writes comprise mode register writes (MRWs) based on commands on the command bus prior to execution of a chip select training mode (CSTM).

9. The apparatus of claim 7, wherein the in-band register writes comprise mode register writes (MRWs) based on commands on the command bus prior to execution of a command/address training mode (CATM).

10. The apparatus of claim 7, wherein the in-band register writes avoid use of multipurpose command (MPC) to train the DFE configuration register and the second configuration register.

11. The apparatus of claim 7, wherein the configuration register update mode command comprises a first multipurpose command (MPC) to enter the configuration register update mode and further comprising a second MPC to exit the configuration register update mode.

12. A computer system comprising:
a memory controller coupled to a command bus; and
a memory chip coupled to the command bus with a command bus interface, the memory chip to receive a configuration register update mode command from the memory controller to trigger the memory chip to enter a configuration register update mode, the memory chip including:
a decision feedback equalization (DFE) configuration register to store a first configuration setting for the command bus interface; and
a second configuration register for a configuration setting other than DFE, the second configuration register to store a second configuration setting for the command bus interface; and
wherein the memory chip is to update the second configuration register with in-band register writes in the configuration register update mode.

13. The computer system of claim 12, wherein the in-band register writes avoid use of sideband bus communication to update the second configuration register.

14. The computer system of claim 12, wherein the memory chip comprises a registering clock driver (RCD), and wherein the configuration register update mode comprises a register word update (RWUPD) mode for the RCD.

15. The computer system of claim 14, wherein the in-band register writes comprise register word (RW) writes based on commands on the command bus, without use of a system management bus (SMBus).

16. The computer system of claim 14, wherein the in-band register writes comprise register word (RW) writes based on commands on the command bus, in combination with use of a system management bus (SMBus).

17. The computer system of claim 12, wherein the memory chip comprises a dynamic random access memory (DRAM) device, and wherein the configuration register update mode comprises a mode register update (MRUPD) mode for the DRAM device.

18. The computer system of claim 17, wherein the in-band register writes comprise mode register writes (MRWs) based on commands on the command bus prior to execution of a chip select training mode (CSTM) and prior to execution of a command/address training mode (CATM).

19. The computer system of claim 17, wherein the in-band register writes avoid use of multipurpose command (MPC) to train the DFE configuration register and the second configuration register.

20. The computer system of claim 12, further comprising one or more of:
a host processor device coupled to the memory controller;
a display communicatively coupled to a host processor coupled to the memory controller;
a network interface communicatively coupled to a host processor coupled to the memory controller; or
a battery to power the computer system.
